(19) United States
(12) Patent Application Publication
(10) Pub. No.: US 2013/0083472 A1
(43) Pub. Date: Apr. 4, 2013

(54) RUGGEDIZED DATA STORAGE AND COMMUNICATION APPARATUS AND METHOD

(71) Applicants: William McMASTER, Las Vegas, NV (US); James STOCKDALE, Clio, CA (US); Robert George KOWOLIK, Las Vegas, NV (US)

(72) Inventors: William McMASTER, Las Vegas, NV (US); James STOCKDALE, Clio, CA (US); Robert George KOWOLIK, Las Vegas, NV (US)

(73) Assignee: IGT, Reno, NV (US)

(21) Appl. No.: 13/628,676

(22) Filed: Sep. 27, 2012

Related U.S. Application Data
(60) Provisional application No. 61/541,871, filed on Sep. 30, 2011.

(51) Int. Cl. H05K 7/00

(52) U.S. Cl. 361/679.31

(57) ABSTRACT

A data storage apparatus includes a housing. A memory device and a data communications circuit are positioned within the housing. The data communications circuit and the link form a portion of a data channel. A source of power is also positioned within the housing to power the communications circuit and provide power for memory reads and writes. The housing is sealed. There are no external electrical contacts on the housing. The data storage apparatus fits within a receptacle during data transfer operations.

### RELATED APPLICATIONS

This application claims the benefit under 35 U.S.C. §119(e) of prior U.S. Provisional Patent Application No. 61/541,871, filed Sep. 30, 2011, which is incorporated herein by reference.

### TECHNICAL FIELD

Various embodiments described herein relate to a system and an apparatus for ruggedized data storage and communication and a method for the same.

### BACKGROUND

In many instances, computers need to be maintained periodically to keep them running at peak performance and to assure the longest possible life of the computer. Maintenance of computers includes software upgrades and periodic checks of the various components to make sure the components are working efficiently with the microprocessor and other components of the computer. If a computer is on a network, software upgrades may be delivered to the individual computers attached to the network from a server over the network. In other instances, there may be no need to utilize network resources when only a very few number of machines needs to be upgraded or when the data to be transferred is very specific and not related to a number of computing devices. Therefore, there are instances where machines are upgraded individually. There are other instances where data needs to be transferred between a particular machine and an external memory source. For example, in gaming, many players carry a players card which they insert into a game. Information or data is taken from the card. As they play a game, information related to the play is also recorded.

Many current data storage devices are not rugged. Current data storage devices, such as a thumb drive, are susceptible to damage from external elements. For example, a thumb drive or flash drive typically will suffer physical damage if water or other liquids contact these drives. Some flash drives have become more rugged, but can still be damaged by water, heat or electrical contact. In addition, current data storage devices have a cap that must be placed over the portion that plugs to a Universal Serial Bus (“USB”) port. Users often lose the caps. This exposes the plug to the environment. The connection may become dirty so that it will not work. Most often the metal plug is elongated and may become bent. Once bent, the flash drive will not fit into the USB port as well. Many times, two USB ports are positioned adjacent one another. If one of the plugs is bent, sometimes it becomes impossible to place another plug into the adjacent port. The plug can also get bent when placed in the USB port. This can damage the port and also prevent the cap for protecting the plug unable to fit over the plug.

Current data storage devices operate on electrical contact with a USB port. There is always a possibility that such contact may create a spark. In many environments, such as on oil platforms or well drilling sites or other environments where there may be combustible gases, use of these devices is dangerous. Plugging in the data storage device could cause a spark resulting in an explosion in these environments.

Current data storage devices can also be removed prematurely during a data transfer. Generally when data is transferred, the sending device indicates an end of the data. This is used to indicate to a device receiving data that all the data is transferred. Current data storage devices can be removed in the middle of a data transfer. This can result in corrupt data or data that has not been completely updated or data that is incomplete.

### SUMMARY OF THE DESCRIBED EMBODIMENTS

A data storage apparatus includes a first portion and a second portion. The first portion is communicatively coupled to a computing device and includes a first link portion. The second portable portion includes a housing, a memory device positioned within the housing, and a data communications circuit within the housing. The data communications circuit includes a second link. The data communications circuit is communicatively coupled to the memory device within the housing. The second portable portion also includes a power source within the housing. The power source is coupled to the memory device and the data communications circuit. The second portable portion has no electrical contacts on the exterior surface. The housing is sealed or hermetically sealed to keep out the elements. The second portion is ruggedized when compared to other portable data devices, such as USB flash drives with caps that cover the electrical contacts for a USB port. The housing can have a shell with an asymmetrical shape.

The first portion has a receptacle therein. The receptacle is sized to receive the housing of the second portable portion. The shape of the housing allows insertion of the second portable portion into the receptacle of the first portion. In one embodiment, the receptacle is accessible at an external surface. The receptacle is shaped to guide the second portable position to a final, substantially fully engaged position.

In one embodiment, the first portion includes a first locking element and the second portable portion includes a second locking element. The first locking element is capable of locking to the second locking element when the second portable portion is within the receptacle such as during a data transfer. The first locking element and the second locking element can be a mechanical lock or a magnetic lock or “latch”. The first link portion and the second link portion are portions can be an optical link, an infrared link, a radio frequency (“RF”) link, or the like. For an optical link, the housing includes a window and the second link portion positioned near the window within the housing. The window in the housing, in one embodiment, includes a fresnel lens to focus the light associated with an optical link.

The first or second portion can include an indicator that is enabled during a data transfer operation. The indicator can be a light viewable external to the housing. In one embodiment, the light is positioned so as to make a substantial portion of the housing illuminate during data transfer operations. The light can illuminate one color during a data transfer. The receptacle can also be provided with a light to indicate readiness for receiving the second portable portion. The power source within the housing is chargeable over the link formed by the first link portion and the second link portion.

A method includes housing a memory portion and a first portion of a data link in a sealed shell having a shape, and placing the shell in a receptacle dimensioned to receive the shell. The receptacle has a second portion of the data link. The receptacle and the shell have no external electrical contacts. The method also includes transferring data between the first portion of the data link and the second portion of the data link while the housing is placed within the receptacle. In one embodiment, the method also includes locking the shell to the receptacle during the data transfer. Locking can be accomplished by magnetically locking the shell to the receptacle during the data transfer or by mechanically locking the shell to the receptacle. The method also includes transferring power to the shell over to the first link portion and the second link portion.

### BRIEF DESCRIPTION OF THE DRAWINGS

The embodiments will be readily understood by the following detailed description in conjunction with the accompanying drawings, wherein like reference numerals designate like structural elements, and in which:

FIG. 1 is a schematic of a storage device, according to an example embodiment.

FIG. 2A is a top view of a storage device, according to an example embodiment.

FIG. 2B is a side view of the storage device shown in FIG. 2A, according to an example embodiment.

FIG. 3 is a schematic of a storage apparatus 300, according to an example embodiment.

FIG. 4A is a top view of a storage device coupled to a receiver, according to an example embodiment.

FIG. 4B is a side view of the storage device coupled to the receiver as shown in FIG. 3A, according to an example embodiment.

FIG. 5 is a flow diagram of a data transfer method, according to an example embodiment.

FIG. 6 shows a schematic diagram of a mechanical lock or latching system, according to an example embodiment.

FIG. 7 shows a schematic diagram of a computer system used in the gaming system, according to an example embodiment.

### DETAILED DESCRIPTION

In the following description, numerous specific details are set forth to provide a thorough understanding of the concepts underlying the described embodiments. It will be apparent, however, to one skilled in the art that the described embodiments may be practiced without some or all of these specific details. In other instances, well known process steps have not been described in detail in order to avoid unnecessarily obscuring the underlying concepts.

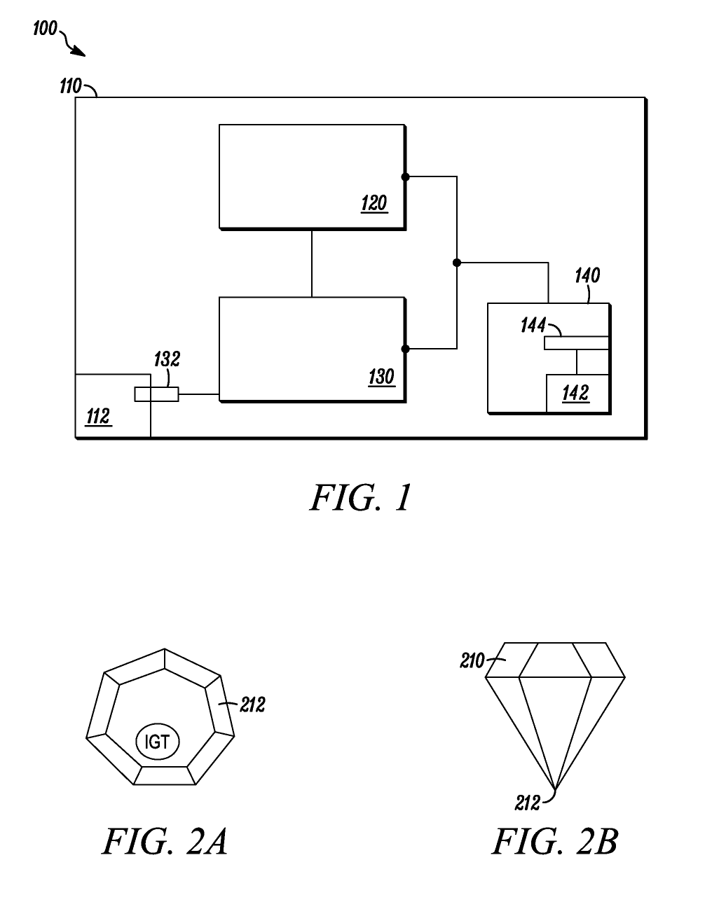

FIG. 1 is a schematic of a storage apparatus 100, according to an example embodiment. The storage apparatus 100 includes a housing 110 or enclosure that is sealed and will not let outside elements within the housing 100. The housing 110 is sealed against moisture, humidity, dust, dirt, electrostatic discharge, and other elements. The components and the storage apparatus are essentially ruggedized and capable of withstanding events that would cause failure in current storage units.

There are components sealed within the housing 110 or enclosure of the storage apparatus 100. The components include a memory device 120 positioned within the housing; and a data communications circuit 130 positioned within the housing 110 or enclosure. The housing or enclosure 110 can be of any shape. The housing is generally sealed. In one embodiment, the housing is hermetically sealed. The communications circuit 130 is communicatively coupled with the memory device 120 and with a link 132. The memory device 120, and the data communications circuit 130 with the link 132 are also within the sealed housing. In one embodiment, the link 132 is an RF link. In another embodiment, the link 132 is a portion of an optical link. When the link 132 is an optical link, the housing 110 or enclosure includes a window 112 through which light associated with the optical link can pass either as it receives information or while it sends information. The optical link can use visual spectrum, infrared spectrum or the ultra-violet spectrum. The optical link can also use a combination of these spectrums (for example, one for sending/one for receiving). Data transmitted by the optical link could also be spread across the spectrum. Also within the housing is a power source 140. The power source is used to operate the communications circuit 130 and specifically is called upon to power reads of the memory device 120 and writes to the memory device 120. The write operation generally takes the most power. A low power write memories, such as memristitve produced by Hewlett Packard of Palo Alto, Calif., USA, can be used in the storage apparatus 100. The use of a low power write memory conserves energy and allows so that more writes and reads could be accomplished before recharging the power source 140. In another approach, the size of the battery could be reduced to make the data storage apparatus 100 more compact and lighter.

In one embodiment, the power source 140 is powered by inductive coupling. An inductive power coupling circuit 142 is associated with the power source. The inductive power coupling circuit 142 provides an inductive coupling for power signals provided by an external device (not shown). The inductive power coupling circuit 142 receives alternating electrical current from the external device or source. The power coupling circuit 142 includes a coil or set of coils that produce a current when a magnetic field produced by a coil external to the housing changes. A rectifier 144 is also associated with the power source 140. The rectifier 144 converts the received alternating current into appropriate levels of direct current. The rectified current can then be applied to perform reads, writes, or other data transfer operations directly, or can recharge a battery within the housing. It should be noted that the housing 110 need not have a battery therein. In addition, in some embodiments, the power source within the housing can include a battery portion and a direct operations portion.

FIG. 2A is a top view of an embodiment of a storage device 200, according to an example embodiment. FIG. 2B is a side view of the storage device 200, according to an example embodiment. Now referring to both FIGS. 2A and 2B, the storage device 200 will be further described. As mentioned previously, the housing can be of any shape. In the embodiment shown in FIGS. 2A and 2B, the housing 210 is formed in an asymmetrical diamond shape. In the embodiment shown in FIGS. 2A and 2B, the housing 210 is a seven-sided shape with subtle asymmetry. The housing 210 includes a window 212 which is located at the pointed portion of the diamond shape. The window 212, in one embodiment is a lens. In one embodiment, the lens is a fresnel lens which is used to focus the outgoing and incoming light to make data transfer more efficient.

The housing 210 has the memory device 120, and the data communications circuit 130 with the link 132 and another embodiment of a power source 240 sealed within the housing. The power source 240 is powered by light transferred through the link 132. The power source 240 includes a photovoltaic array and is located in the housing 210. The photovoltaic array converts the light energy sent to and through the link to a stable power source for the memory device 120, the data communications circuit 130, and any control electronics. The storage device 200 may include a battery to provide a source of additional energy which may be needed for certain types of memory devices 120 to facilitate writing or retaining information. The power source 240 described above provides a recharge capability for any on-board battery.

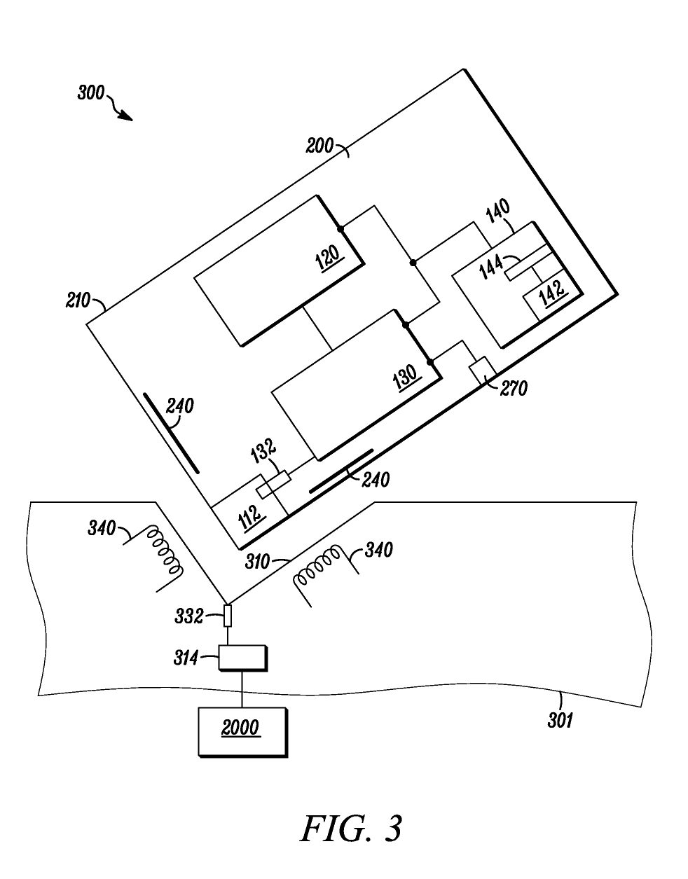

FIG. 3 is a schematic of a storage apparatus 300, according to an example embodiment. The data storage apparatus 300 includes a first portion 301 having a receptacle 310 therein, and a second portable portion or a data storage device 200. The data storage device 200 is similar to the data storage device 100 described above. The first portion 301 is communicatively coupled to a computing device 2000 (further detailed in FIG. 9) and includes a first link portion 332 and a data channel 314 that is connected to a bus associated with the computing device. The second portable portion 200 includes a housing 210, a memory device 120 positioned within the housing, and a data communications circuit 130 within the housing 210. The data communications circuit 130 includes a second link portion 132. The data communications circuit 130 is communicatively coupled to the memory 120. The second portion 200 also includes a power source 140 within the housing. The power source 140 is coupled to the memory device 120 and the data communications circuit 130. The power source 140 can obtain power by way of inductive coupling between the first portion 301 and the second portion 200, or can obtain power from light used as part of an optical link between link 332 and link 132.

The first portion 301 has a receptacle 310 therein. The receptacle is sized to receive the housing 210 of the second portable portion 200. The housing 210, of the second portable portion 200 is asymmetrically shaped. In one embodiment, the shape also limits insertion of the second portable portion into the receptacle of the first portion to a single orientation. The receptacle is shaped to guide the housing 210 of the second portable portion 200 to a final engaged position with the receptacle 310. When inserted correctly, the first link 332 is aligned or substantially aligned with the second link 132. In one embodiment, the receptacle 310 is externally accessible.

As shown, in FIG. 3, there are no exposed electrical contacts on the surface of the receptacle or on the surface of the housing 210. The housing is sealed or hermetically sealed to keep out harmful elements. Therefore, the data storage apparatus 300 can be used in various environments where other data storage apparatus might be prone to failure or might pose a danger. For example, the data storage apparatus 300 can be used in environments where explosive gases may be present, such as in farm elevators or offshore oil rigs.

In one embodiment, the first portion 301 includes a first locking element 340 and the second portable portion 200 includes a second locking element 240. The first locking element 340 is capable of locking to the second locking element 240 when the second portable portion 200 is positioned or fully inserted within the receptacle 310. The first locking element 340 is locked to the second locking element 240 during a data transfer. As shown, the first locking element 340 and the second locking element 240 are latched magnetically. As shown, the first locking element 340 includes an induction coil capable of producing a magnetic force when alternating current is passed through the coil. The second locking element includes a ferrous metal plate 240 within the housing 210 of the second portable portion 200. In another embodiment, a coil associated with the power source is used for creating the magnetic lock. In this embodiment, the same coils used to transfer power to the power source are used to lock the second portable portion 200 with respect to the receptacle 310 of the first portion 301.

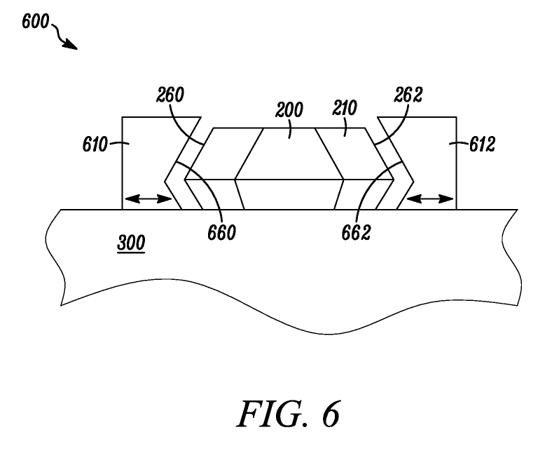

In the alternative, a mechanical lock or latching mechanism can be formed on the first portion 301 and on the second portion 200. FIG. 6 shows a mechanical lock or latching system 600. The mechanical locking or latching mechanism includes a first locking block 610 slidably attached to the first portion 301, and a second locking block 612 slidably attached to the first portion 301. The first locking block 610 includes a surface 660 shaped to engage one side, such as side 260 of the data storage device 200. The second locking block 612 includes a surface 662 shaped to engage another side, such as side 262 of the data storage device 200. When the data storage device 200 is properly placed into the receptacle 310 of the first portion 301, such as a stand, the data storage device 200 is fully engaged with the receptacle 310. This allows for proper alignment of the wall 660 of the first locking block 610 to fully engage the wall 260 of the storage device 200. Similarly, full engagement also allows for proper alignment of the wall 662 of the first locking block 612 to fully engage the wall 262 of the storage device 200. The first locking block 610 and the second locking block 612 are slidably attached to the first portion 301 so that the first locking block slides or is moved into engagement with a side 260 of the storage device 200. Similarly, the second locking block 612 slides or is moved into engagement with the side 262 of the storage device 200. Before a write or read operation is to commence, the blocks 610 and 612 are moved into engagement with the storage device 200. This is done by software control from a controller or from a processor associated with the computer system 2000. If the blocks 610, 612 meet a resistance force, the blocks 610, 612 will move to a disengaged position and the write or read operation will not be enabled. If a resistance force smaller than a threshold force is met, the blocks 610, 612 are moved into the locking position where they substantially lock the storage device 200 in position. Once locked, the software enables read or write commands. Once done with read or write operations, the software issues a command to move the blocks 610, 612 to the disengaged position. The data storage device 200 can then be safely removed from the receptacle 310. The mechanical lock or latching mechanism is enabled by a signal indicating data transfer is about to start. The first portion 301 and the second portion 200 stay latched during the data transfer.

In some embodiments, the first portion 301 or the second portion 200 includes an indicator 270 that is enabled during a data transfer operation. The indicator 270 can be a light viewable external to the housing. In one embodiment, the light is positioned so as to make a substantial portion of the housing 210 illuminate during data transfer operations. As mentioned previously, the power source 140 within the housing can include a battery. The battery is chargeable, in one embodiment, over the link formed by the first link portion 332 and the second link portion 132. In another embodiment, the induction coil 340 can be provided with alternating electrical current to produce a similar current in the inductive power coupling circuit 142 which is rectified using the rectifier 144 to a current level which can be used to charge a battery or effectuate data transfer operations directly.

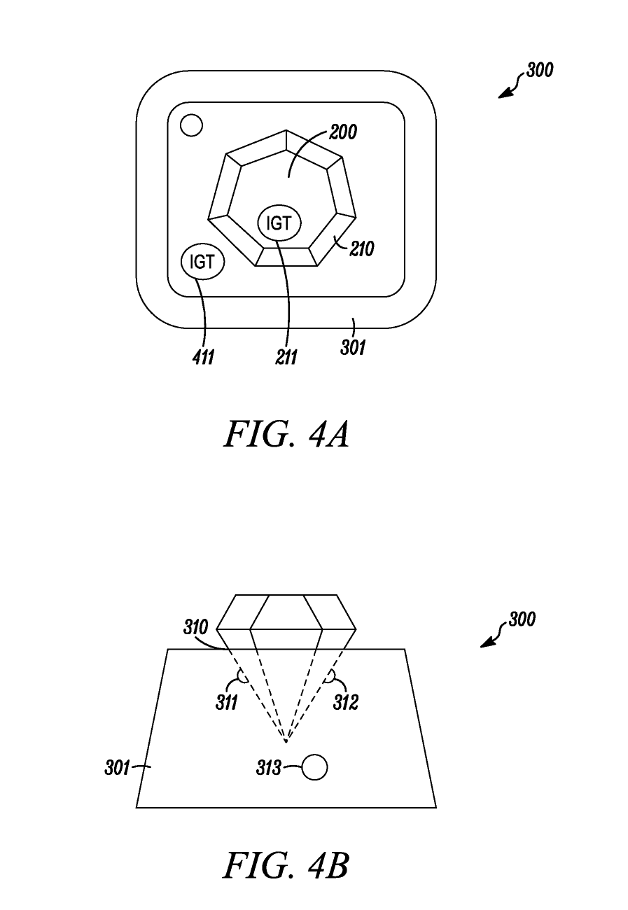

FIG. 4A is a top view of a storage apparatus 300 that includes a storage device 200 coupled to a first portion 301 that includes a receptacle or receiver 310, according to an example embodiment. FIG. 4B is a side view of the storage apparatus 300 having the storage device 200 coupled to the receptacle or receiver 310 as shown in FIG. 4A, according to an example embodiment. Now referring to both FIGS. 4A and 4B, the storage apparatus 300 will be further described. The housing 210 of the storage device 200 is in the form of an asymmetrical diamond shape. As shown in FIGS. 4A and 4B, the housing 210 is a seven-sided shape with subtle asymmetry. The asymmetry of the housing 210 of the storage device 200 allows alignment of optical elements or links 132, 332 (shown in FIG. 3) when inserted into the receiver or receptacle 310. The receiver or receptacle 310 includes a cavity that receives the seven-sided shape of the housing 210 of the data storage device 200. The housing 210 can only be fully engaged with the receptacle 310 when the housing is in one orientation. When fully engaged, the links 132, 332 (shown in FIG. 3) are aligned and closely spaced so that data can be transferred over these links in an effective and efficient manner. The sloping sides of the housing 210 and the sloping sides of the receptacle 310 serve to guide the housing 210 into a fully engaged position within the receptacle 310. The first portion 301 features an index or mark 411 and the housing 210 features a mark 211 that can be used to aid in initially positioning the housing 210 of the data storage device 200 with respect to the first portion so that it will be correctly orientated to fully engage the receptacle 310 of the first portion.

The data storage device 200 can be illuminated during the data transfer. The first portion 301, such as the stand shown in FIG. 4B, includes a first light emitting diode (“LED”) 311, and a second LED 312. The pair of LEDs are side firing LEDs that provide varying levels of illumination. In one embodiment, the LEDs 311, 312 are blue side firing LEDs and produce a low level of light when the data storage device 200 is connected to the reader or first portion 301. When data is being transferred between the data storage device 200 and the reader or first portion 301, the LEDs produce a high level of illumination. There is no level of illumination when there is no data transfer operation going on which indicates that the data storage device 200 can be removed from the reader or stand or receptacle 310 of the first portion 301. In another embodiment another LED 313 is associated with the base or first portion 301. The LED 313 illuminates when the first portion 301 or reader is connected to a host system, such as the computer 2000 and can accept the data storage device 200. This LED 313 illuminates the base, reader or first portion 301. In some embodiments, the color of the LED 313 is different from the color for illuminating the data storage device 200 during data transfer. The LED 313 is green, in one embodiment, indicating that the base or reader or first portion 301 is ready to go.

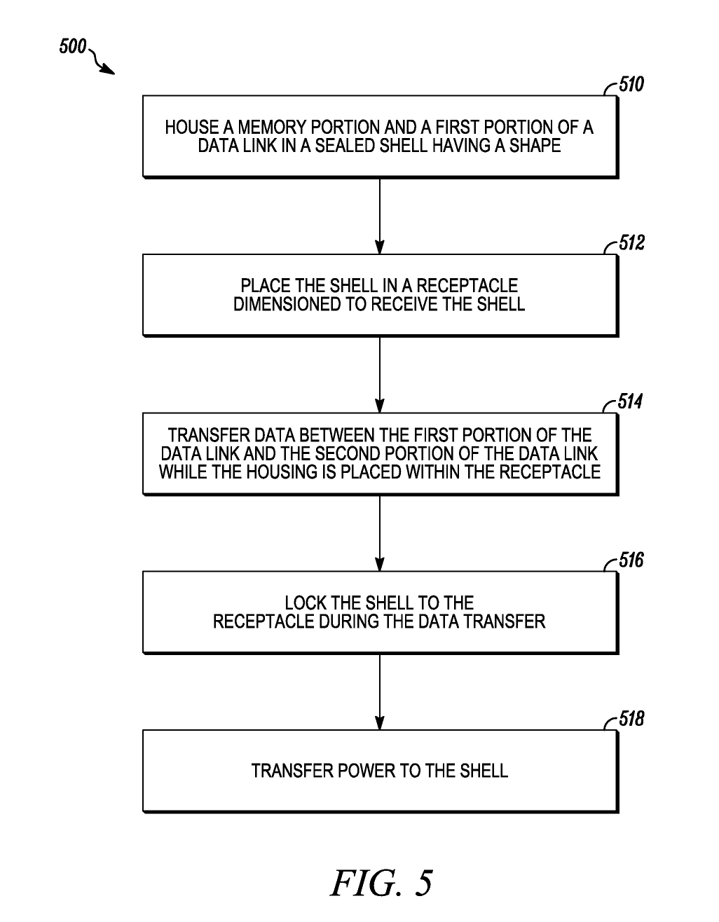

FIG. 5 is a flow diagram of a data transfer method 500, according to an example embodiment. The method 500 includes housing a memory portion and a first portion of a data link in a sealed shell having a shape 510, and placing the shell in a receptacle dimensioned to receive the shell 512. The receptacle has a second portion of the data link. The receptacle and the shell have no external electrical contacts. The method 500 also includes transferring data between the first portion of the data link and the second portion of the data link while the housing is placed within the receptacle 514. In one embodiment, the method 500 also includes locking the shell to the receptacle during the data transfer 516. Locking can be accomplished by magnetically locking the shell to the receptacle during the data transfer or by mechanically locking the shell to the receptacle. The method 500 also includes transferring power to the shell 518. Power can be transferred over to the first link portion and the second link portion. Power can also be transferred using an inductive coil driven by an alternating current to produce a magnetic field. The shell includes ferrous plates which are held by the magnetic force produced. In another embodiment, the shell includes inductive coils which are held by a magnetic field associated with inductive coils in the base or first portion 301.

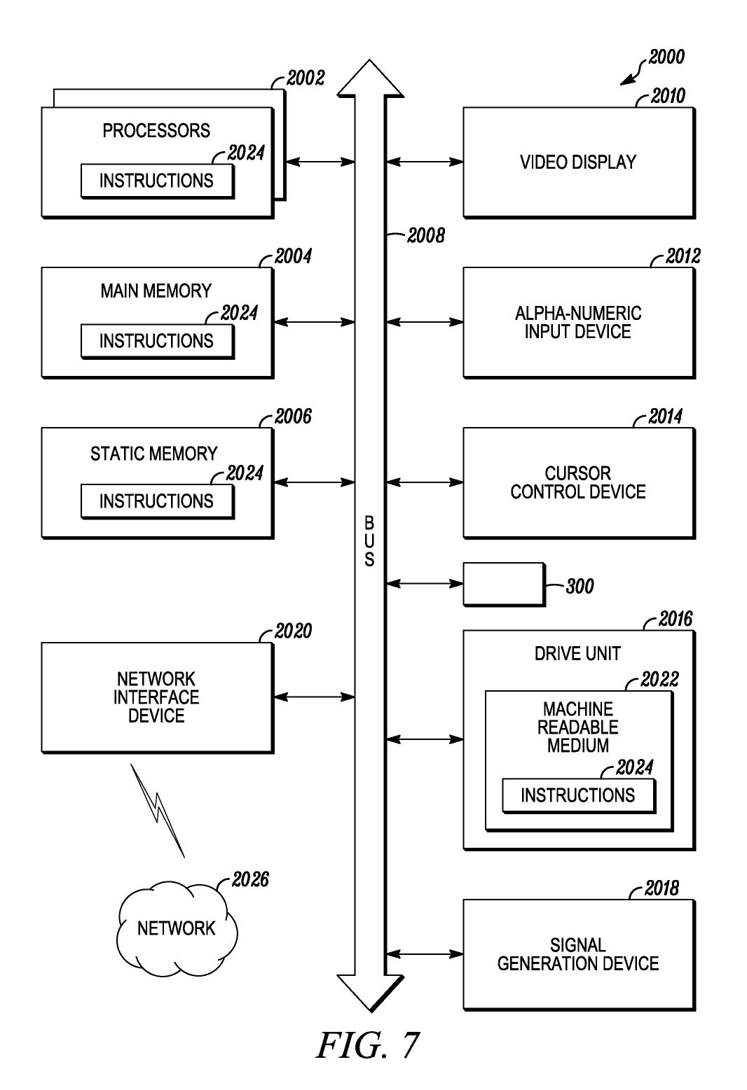

FIG. 7 shows a diagrammatic representation of a computing device for a machine in the example electronic form of a computer system 2000. In various example embodiments, the machine operates as a standalone device or can be connected (e.g., networked) to other machines. In a networked deployment, the machine can operate in the capacity of a server or a client machine in a server-client network environment, or as a peer machine in a peer-to-peer (or distributed) network environment. The machine can be a personal computer (PC), a tablet PC, a set-top box (STB), a Personal Digital Assistant (PDA), a cellular telephone, a portable music player (e.g., a portable hard drive audio device such as an Moving Picture Experts Group Audio Layer 3 (MP3) player, a web appliance, a network router, a switch, a bridge, or any machine capable of executing a set of instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein.

The example computer system 2000 includes a processor or multiple processors 2002 (e.g., a central processing unit (CPU), a graphics processing unit (GPU), arithmetic logic unit or all), and a main memory 2004 and a static memory 2006, which communicate with each other via a bus 2008. The computer system 2000 can further include a video display unit 2010 (e.g., a liquid crystal displays (LCD) or a cathode ray tube (CRT)). The computer system 2000 also includes an alphanumeric input device 2012 (e.g., a keyboard), a cursor control device 2014 (e.g., a mouse), a disk drive unit 2016, a signal generation device 2018 (e.g., a speaker) and a network interface device 2020. The data storage apparatus 300 is also attached to the bus 2008.

The disk drive unit 2016 includes a computer-readable medium 2022 on which is stored one or more sets of instructions and data structures (e.g., instructions 2024) embodying or utilized by any one or more of the methodologies or functions described herein. The instructions 2024 can also reside, completely or at least partially, within the main memory 2004 and/or within the processors 2002 during execution thereof by the computer system 2000. The main memory 2004 and the processors 2002 also constitute machine-readable media.

The instructions 2024 can further be transmitted or received over a network 2026 via the network interface device 2020 utilizing any one of a number of well-known transfer protocols (e.g., Hyper Text Transfer Protocol (HTTP), CAN, Serial, or Modbus).

While the computer-readable medium 2022 is shown in an example embodiment to be a single medium, the term “computer-readable medium” should be taken to include a single medium or multiple media (e.g., a centralized or distributed database, and/or associated caches and servers) that store the one or more sets of instructions and provide the instructions in a computer readable form. The term “computer-readable medium” shall also be taken to include any medium that is capable of storing, encoding, or carrying a set of instructions for execution by the machine and that causes the machine to perform any one or more of the methodologies of the present application, or that is capable of storing, encoding, or carrying data structures utilized by or associated with such a set of instructions. The term “computer-readable medium” shall accordingly be taken to include, but not be limited to, solid-state memories, optical and magnetic media, tangible forms and signals that can be read or sensed by a computer. Such media can also include, without limitation, hard disks, floppy disks, flash memory cards, digital video disks, random access memory (RAMs), read only memory (ROMs), and the like.

The example embodiments described herein can be implemented in an operating environment comprising computer-executable instructions (e.g., software) installed on a computer, in hardware, or in a combination of software and hardware. Modules as used herein can be hardware or hardware including circuitry to execute instructions. The computer-executable instructions can be written in a computer programming language or can be embodied in firmware logic. If written in a programming language conforming to a recognized standard, such instructions can be executed on a variety of hardware platforms and for interfaces to a variety of operating systems. Although not limited thereto, computer software programs for implementing the present method(s) can be written in any number of suitable programming languages such as, for example, Hyper text Markup Language (HTML), Dynamic HTML, Extensible Markup Language (XML), Extensible Stylesheet Language (XSL), Document Style Semantics and Specification Language (DSSSL), Cascading Style Sheets (CSS), Synchronized Multimedia Integration Language (SMIL), Wireless Markup Language (WML), Java™, Jini™, C, C++, Perl, UNIX Shell, Visual Basic or Visual Basic Script, Virtual Reality Markup Language (VRML), ColdFusion™ or other compilers, assemblers, interpreters or other computer languages or platforms.

The present invention provides a hermetically sealed rugged storage device 200 that does not require any electrical contact to connect with a host device, such as the computer 2000. The storage device 200 can include any type of memory 120, such as flash storage, an SD flash card, mini SD card or micro SD card, or other similar flash storage media. The flash storage or memory 120 is coupled to a communication circuit 130. The communication circuit 130 and the memory 120 are housed inside a hermetically sealed shell. The communication circuit 130 communicates with the host device, such as computer 2000 over a first link 332, and a second link 132. The host device has a compatible communication circuit, such as data channel 314. This can be embodied in the form of a universal serial bus (“USB”) device that plugs into a universal serial bus.

In one embodiment, the communication circuit 130 uses optical communication to communicate with the data channel 314 associated with the host computer 2000. The optical communication can be in the visual, infrared, ultraviolet spectrum, or a combination of two or all three spectrums. In this embodiment, the sealed shell is designed such that it is compatible with the optical communication being used. For example, a window 112 that allows light to pass through is provided if light in the visual spectrum is used. In another embodiment, the communication circuit uses short range RF to communicate with the data channel 314 associated with the stand or host portion 301.

The shell or housing 210 of the storage device 200 is hermetically sealed and has a unique shape. In one embodiment, the shape is non-symmetrical. This allows the storage device to be “mated” with the reader device in only one possible orientation. This allows alignment of the link 132 in the storage device 200 with the link 332 in the reader device or stand 301 as required, such as when the link 132 and link 332 are an optical reader and optical transmitter, respectively. Mating or aligning entails placing the storage device 200 on a reader device 301 in the one orientation that allows for a fit and a proper alignment.

The communication circuit 130 includes the hardware and software to send and receive data to and from the reader device or stand 301. For example, an optical communication device includes an optical transmitting device and an optical sensing device (or a receiver). The transmitting and sensor devices can use the visual spectrum, infrared spectrum or the ultra-violet spectrum. They can also use a combination of these spectrums (one for sending/one for receiving), or data being spread across the spectrum. When the storage device 200 is “mated” with the reader device 301 an inductive field generated by the reader device or stand 301 will hold or magnetically lock the storage device 200 within the reader device or stand 301. The inductive field, in one embodiment, is generated in response to data being transferred between the reader device or stand 301 and the storage device 200. Locking the storage device 200 to the reader or stand 301 prevents accidental removal when data in being read/written. Once read/write operations are complete, a software instruction disables the inductive field thereby removing the magnetic lock between the stand 301 and the data storage device 200. Alternatively, a mechanical latch may be used which can be enabled and disabled by software control.

In an alternate embodiment, storage device communicates with reader device using RF communication. One such example of RF communication that can be used over short range is the NFC standard. The reader and the storage device use the NFC standards to communicate with each other over short distances. When the storage device is “mated” or substantially fully engaged with the reader, the reader begins communication to look for a storage device.

### General Applications

One application of the present invention is to replace conventional flash storage devices whereby the storage devices are subject to extreme physical conditions such as rugged handling or variations of temperature or humidity, or may be exposed to moisture or humidity. Another application is in conditions which require extreme electrical safety—where a minor spark may be dangerous—such as where extremely volatile chemicals are stored or maintained.

### Gaming Applications

One application of such a storage device is to replace player tracking cards. Player tracking cards are associated with award programs whereby the player receives varies awards and incentives based on the amount of play and type of play. The storage device 200 (second portable portion) is built to withstand careless handling by the players. The players can take the device with them without worrying about corrupting data. With the additional amount of storage available on the device, it can provide extended functionality that is currently not available. For example, it can store images or video of a player's gameplay. It can also store play at home games whereby player activity in “offline” play accumulates points and awards that are available to the player on the casino slot game.

### Maintenance Applications

Another application is for slot technicians. This device can be used to store firmware upgrades or new slot games to be loaded on slot machines. The technician can simply drop the device on a reader and that can initiate firmware upgrade with a corresponding software instruction or code download. The storage device 200 mated with the receptacle 300 can also include other service applications, such as downloading data resident to a specific machine. Data could include warranty information, or conditions under which the machine was operated which generated maintenance warnings.

The “window” described in the above embodiments can include the entire surface area of the device and receptacle if these devices were constructed of a material that would allow the light spectra of interest to pass unhindered. In this case, alignment of the transmitting and receiving elements is all that is required. Lenses are completely optional.

Furthermore, it is contemplated that an additional embodiment can be made without the locking elements. In other embodiments, methods of software interaction would guarantee data reliability should the device be removed while a data transfer was in progress.

This invention is targeted toward general rugged data storage that can be used in any application. The above description of the rugged data storage in a gaming application in no way limits the invention to the gaming industry. While descriptions of the use of the invention in a gaming environment are valid, they are not key to the use of the invention and should in no way limit the patent.

Positioning the data transfer indicator LEDs in the “reader” portion, attached to the computer system reduces the power requirements of the removable device and would probably be preferred, though location of the indicator in either portion is possible.

It is further contemplated that the device could actually be of any number of shapes and is not limited to a diamond shape. For example, a substantially flat device which is coupled for power when placed in proximity to a substantially flat receptacle is contemplated. The same device could also transfer data via short range RF communication. This could be embodied as a “data card” device that would be placed on a reader pad and data transfer initiated.

The foregoing description, for purposes of explanation, used specific nomenclature to provide a thorough understanding of the invention. However, it will be apparent to one skilled in the art that the specific details are not required in order to practice the invention. Thus, the foregoing descriptions of specific embodiments of the present invention are presented for purposes of illustration and description. They are not intended to be exhaustive or to limit the invention to the precise forms disclosed. It will be apparent to one of ordinary skill in the art that many modifications and variations are possible in view of the above teachings.

The embodiments were chosen and described in order to best explain the principles of the invention and its practical applications, to thereby enable others skilled in the art to best utilize the invention and various embodiments with various modifications as are suited to the particular use contemplated. It is intended that the scope of the invention be defined by the following claims and their equivalents.

While the embodiments have been described in terms of several particular embodiments, there are alterations, permutations, and equivalents, which fall within the scope of these general concepts. It should also be noted that there are many alternative ways of implementing the methods and apparatuses of the present embodiments. It is therefore intended that the following appended claims be interpreted as including all such alterations, permutations, and equivalents as fall within the true spirit and scope of the described embodiments.

What is claimed:

1. A data storage apparatus comprising:
a housing;
a window within the housing;
a memory device positioned within the housing; and
a data communications circuit within the housing, the data communications circuit including a link positioned near the window, the data communications circuit communicatively coupled to the memory.

2. The data storage apparatus of claim 1 wherein the housing is sealed.

3. The data storage apparatus of claim 1 wherein the housing is hermetically sealed.

4. The data storage apparatus of claim 1 wherein the link includes an optical data link.

5. The data storage apparatus of claim 1 wherein the link includes an optical data link and wherein the window in the housing includes a fresnel lens.

6. The data storage apparatus of claim 1 further including an indicator that is enabled when during a data transfer operation.

7. The data storage apparatus of claim 1 further including a power source positioned within the housing.

8. The data storage apparatus of claim 7 wherein the power source is charged over the link.

9. The data storage apparatus of claim 1 further including a portion of a locking element, the portion of the locking element engaged during a data transfer operation.

10. The data storage apparatus of claim 9 wherein the portion of the locking element is a portion of a mechanical locking mechanism.

11. The data storage apparatus of claim 9 wherein the portion of the locking element includes a ferrous metal associated with the housing.

12. The data storage apparatus of claim 1 wherein the housing is asymmetrically shaped.

13. A data storage apparatus comprising:
a first portion communicatively coupled to a computing device, the first portion including a first link portion;
a second portable portion further comprising:
a housing;
a memory device positioned within the housing;
a data communications circuit within the housing, the data communications circuit including a second link portion, the data communications circuit communicatively coupled to the memory; and
a power source within the housing, the power source coupled to the memory device and the data communications circuit.

14. The data storage apparatus of claim 13 wherein the first portion has a receptacle therein, the receptacle sized to receive the housing of the second portable portion, and wherein the housing is asymmetrically shaped.

15. The data storage apparatus of claim 14 wherein the receptacle is externally accessible.

16. The data storage apparatus of claim 13 wherein the first portion has a receptacle therein, the receptacle sized to receive the housing of the second portable portion.

17. The data storage apparatus of claim 16 wherein the first portion includes a first locking element and the second portable portion includes a second locking element, the first locking element capable of locking to the second locking element when the second portable portion is positioned within the receptacle.

18. The data storage apparatus of claim 17 wherein the first locking element is locked to the second locking element during a data transfer.

19. The data storage apparatus of claim 17 wherein the first locking element and the second locking element form a mechanical lock.

20. The data storage apparatus of claim 15 wherein the first locking element and the second locking element are latched magnetically.

21. The data storage apparatus of claim 13 wherein the housing is sealed.

22. The data storage apparatus of claim 13 wherein the first link portion and the second link portion are portions of an optical link.

23. The data storage apparatus of claim 22 wherein the housing includes a window, the second link portion positioned within the housing near the window.

24. The data storage apparatus of claim 13 wherein the first link portion and the second link portion are portions of a radio frequency link.

25. The data storage apparatus of claim 13 wherein the second portion further comprises an indicator that is enabled during a data transfer operation.

26. The data storage apparatus of claim 13 wherein the power source is chargeable over the link formed by the first link portion and the second link portion.

27. A method comprising:
housing a memory portion and a first portion of a data link in a sealed shell having a shape;
placing the shell in a receptacle dimensioned to receive the shell, the receptacle having a second portion of the data link, the receptacle and the shell having no external electrical contacts; and
transferring data between the first portion of the data link and the second portion of the data link while the housing is placed within the receptacle.

28. The method of claim 27 further comprising locking the shell to the receptacle during the data transfer.

29. The method of claim 27 further comprising magnetically locking the shell to the receptacle during the data transfer.

30. The method of claim 27 further comprising transferring power to the shell over to the first link portion and the second link portion.
